(19) United States
(12) Patent Application Publication
(10) Pub. No.: US 2014/0272314 A1
(43) Pub. Date: Sep. 18, 2014

(54) COATED ARTICLE INCLUDING BROADBAND AND OMNIDIRECTIONAL ANTI-REFLECTIVE TRANSPARENT COATING, AND/OR METHOD OF MAKING THE SAME

(71) Applicant: Guardian Industries Corp., Auburn Hills, MI (US)

(72) Inventor: Vijayen S. VEERASAMY, Ann Arbor, MI (US)

(21) Appl. No.: 13/835,278

(22) Filed: Mar. 15, 2013

(51) Int. Cl. G02B 1/11; H01L 31/0216

(52) U.S. Cl. CPC G02B 1/11; H01L 31/02168
USPC 428/172; 438/72; 427/162; 427/457

(57) ABSTRACT

Certain example embodiments involve the production of a broadband and at least quasi-omnidirectional antireflective (AR) coating. The concept underlying certain example embodiments is based on well-established and applied mathematical tools, and involves the creation of nanostructures that facilitate these and/or other features. Finite element (FDTD) simulations are performed to validate the concept and develop design guidelines for the nanostructures, e.g., with a view towards improving visible transmission. Certain example embodiments provide such structures on or in glass, and other materials (e.g., semiconductor materials that are used to convert light or EM waves to electricity) alternatively or additionally may have such structures formed directly or indirectly thereon.

Certain example embodiments of this invention relate to anti-reflective (AR) coatings, and/or methods of making the same. More particularly, certain example embodiments of this invention relate to coated articles including broadband and omnidirectional AR transparent coatings, and/or methods of making the same.

### BACKGROUND AND SUMMARY OF EXAMPLE EMBODIMENTS OF THE INVENTION

Glass (including low-iron soda lime silica based glass, for example) is virtually transparent for wavelengths longer than 400 nm. However, Fresnel reflection is known to cause about 4% of the incident light to reflect from a major surface thereof, with about 8% reflecting from the two major surfaces of a glass substrate. This reflection is undesirable in many applications. For example, high reflections also may be aesthetically undesirable in some cases. Moreover, this reflection can potentially degrade the efficiency of an associated electronic device (e.g., both in receiving and transmitting modes). For instance, reflections can limit the amount of light passed to a solar photovoltaic cell and thus reduce its efficiency. As another example, the luminous efficacy of lighting applications may be reduced.

Notwithstanding this known deficiency, glass remains the prime substrate or superstrate in many long-term applications because reliable techniques exist to mitigate Fresnel losses. For instance, single layer quarter-wave AR (QWAR) coatings abound in the market. Unfortunately, however, the general unavailability of materials with a desired, exact refractive index value oftentimes means that the performance of such QWAR coatings deviates from optimum or desired levels. In the case of low refractive index substrates such as soda lime silica based glass, an ideal single-layer coating in air would generally involve a material with a refractive index of 1.2. Yet there presently is no known conventional non-porous inorganic material that has such a low refractive index.

Fundamentally, single-layer AR (SLAR) coatings generally can reduce reflection only for one specific wavelength at normal incidence. SLAR coatings thus are generally inherently unable to exhibit spectrally “broadband” reduction in reflectance over a wide range of angles of incidence.

Multi-layer stacks of materials with different refractive indices have been used in order to achieve broadband reduction in reflection. AR coatings with specular surfaces made of multiple discrete layers of non-absorbing materials, for example, can exploit thin-film interference effects, e.g., to reduce reflectance while improving transmittance. However, such coatings still are generally angular-bandwidth limited.

Recently, it has been shown that discrete multilayer AR coatings can outperform continuously graded AR coatings, thereby offering powerful techniques to reduce reflectance. However, optimization of multilayer AR coatings is challenging because of the extremely large and complex dimensional space of possible solutions. In addition, the practice of depositing or otherwise forming such layers frequently require laborious real-time control to be implemented, even in some of the most advanced currently available coaters.

Thus, it will be appreciated that there is a need in the art for coated articles including broadband and/or omnidirectional AR transparent coatings, and/or methods of making the same.

In certain example embodiments, there is provided a method of making a coated article comprising an AR coating supported by a glass substrate. A solution is dispensed onto at least one major surface of the glass substrate. The solution is dried at a first temperature. Benard cells are formed and/or allowed to form during the dispensing and/or drying, with the Benard cells causing nanostructures to self-assemble on the at least one major surface of the glass substrate in accordance with a desired template. The desired template exhibiting waveguide modes that approximate: (a) a transverse magnetic (TMz) mode in which

$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$

and/or (b) a transverse electric (TEz) mode in which

$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3}} {α}^{2} + O ( {α}^{4} ) ,$$

where a₀=f/∈₂−(1−f)/∈₁, ∈₀=∈₂f−∈₁(1−f), and a=2R/λ₀. At least a part of the solution is cured at a second temperature that is higher than the first temperature in forming the AR coating.

According to certain example embodiments, the solution may asymmetrically phase separate into first and second phases.

According to certain example embodiments, the AR coating may provide an average transmission gain of 2-3% (more preferably 3-4%) are achieved over a wavelength range of 400-1200 nm. This AR feature may be provided over substantially all incidence angles (e.g., preferably at angles at least 30 degrees from normal, more preferably at least 45 degrees from normal, still more preferably at least 60-75 degrees from normal, and sometimes at least 80-85 degrees from normal).

According to certain example embodiments, the nanostructures may comprise a material that, if coated separately, would have an index of refraction of at least 1.8. The nanostructures may in certain example embodiments comprise Ti, Si, and/or Ce. Anatase TiO₂, for instance, may be used in certain example embodiments.

These example methods may be used to make electronic devices (e.g., photovoltaic devices, touch screen devices, display devices, etc.), windows (e.g., insulating glass units, vacuum insulating glass units, etc., for commercial and/or residential uses). In general, in certain example embodiments, a coated article may be made in accordance with any of the example techniques set forth herein and then built into an intermediate and/or end product.

One example involves a method of making a photovoltaic device, which may comprise (for example): providing a coated article made according to the method of the example techniques set forth herein; and on a surface opposite the AR coating, forming at least the following layers, in order, moving away from the substrate, a first transparent conductive coating, a first semiconductor layer, one or more absorbing layers, a second semiconductor layer, and a second transparent conductive coating.

In a similar vein, certain example embodiments relate to a coated article and/or intermediate or end product produced in accordance with any of the techniques and/or having any of the features set forth herein. In this regard, certain example embodiments relate to a coated article, comprising: a glass substrate; and an antireflective (AR) coating formed on at least one major surface of the substrate. The AR coating is patterned so as to exhibit waveguide modes that approximate (a) a TMz mode in which

$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$

and (b) a TEz mode in which

$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3}} {α}^{2} + O ( {α}^{4} ) ,$$

where a₀=f/∈₂−(2−f)/∈₁, ∈₀=∈₂f−∈₁(1−f), and a=2R/λ₀. The AR coating may, for example, provide an average transmission gain of at least 2% achieved over a wavelength range of 400-1200 nm at substantially all angles of incidence.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1a is an image showing nanostructures formed on soda lime silica based glass;

FIG. 1b shows the piecewise permittivity in a one-dimensional case, for simplicity;

FIG. 2 is a schematic cross-sectional view of a typical nanostructure with parameters h and d that may be optimized for transmittance;

FIG. 3a is a partial perspective view of a formulation of the problem to be solved;

FIG. 3b is a simplified two-dimensional cross-sectional view of the array of dielectric rods shown in FIG. 3a;

FIG. 4 plots reflectance vs. height and wavelength at a fixed cone diameter in connection with a coating designed in accordance with the example model set forth herein;

FIG. 5 is a cross-sectional view schematically illustrating a cone-inclusive model that includes a joint probability distribution as to both the diameters and the height of the cones in accordance with certain example embodiments;

FIG. 6 is a graph plotting measured reflectance of substrates including conventional high-quality antireflective (AR) films, as well as a sample AR film produced in accordance with certain example embodiments;

FIG. 7 is a flowchart illustrating an example approach for forming an AR coating in connection with certain example embodiments;

FIG. 8 is a flowchart illustrating another example approach for forming an AR coating in connection with certain example embodiments; and

FIG. 9 is an example photovoltaic device incorporating an AR coating made in accordance with certain example embodiments.

### DETAILED DESCRIPTION OF EXAMPLE EMBODIMENTS OF THE INVENTION

Certain example embodiments involve the production of a broadband and at least quasi-omnidirectional antireflective (AR) coating. The concept underlying certain example embodiments is based on well-established and applied mathematical tools, and involves the creation of nanostructures that facilitate these and/or other features. Finite element (FDTD) simulations are performed to validate the concept and develop design guidelines for the nanostructures, e.g., with a view towards improving visible transmission. Certain example embodiments provide such structures on or in glass, and other materials (e.g., semiconductor materials that are used to convert light or EM waves to electricity) alternatively or additionally may have such structures formed directly or indirectly thereon.

During a comparative study of ion beam milling of both aged and fresh glass, the inventor observed clear differences in the optical properties of the associated substrates. It emerged that the optical transmittance (Tvis) of aged glass is greater than freshly prepared glass of the same composition and thickness. The difference was found to be statistically significant at the 4-sigma level. It was found that the difference in transmittance was greatest in the case when both surfaces were aged and ion beam treated at 45 degrees, suggesting a surface effect.

In-depth spectral characterization of the glass by a spectro-photometer and ellipsometry showed that the reflectance (Rvis) of these films were accordingly diminished over a large portion of the visible spectrum. This effect, when correlated with surface studies (e.g., atomic force microscopy, and electron energy loss spectroscopy/x-ray photoelectron spectroscopy) showed both morphological as well as chemical changes to the glass surface. Though the structures formed were generally not regular, a spatial Fourier transform of the surface profile revealed a trend, whereby a strong spatial harmonic was seen as being correlated to the AR behavior of the aged glass surfaces treated with the ion beam.

In addition, enrichment of hydrated alkali ions was found at the surface in those areas where these nanostructures are formed. Thus, the inventor surmised that a quasi-regular structured surface composed of a material with a refractive index close to the substrate behaves as an anti-reflector and enhances the optical transparency of the surface. To back up this conjecture, the inventor developed a mathematical model based on Floquet's Little Theorem and performed calculations that showed a closely-packed array of cone-shaped protuberances, with a spacing and height of 180-400 nm and 300-600 nm, respectively reduces (and in some cases minimizes) reflectance. The regular modulation of the surface may be considered refraction matching, and the reflectivity at the surface was found to decrease by two orders of magnitude compared with that of a flat surface.

In this regard, FIG. 1a is an image showing nanostructures formed on soda lime silica based glass; and FIG. 1b shows the piecewise permittivity in a one-dimensional case, for simplicity.

Based on observations and modeling, the inventor developed an algorithm that allows nanostructures to be designed so as to achieve desired broad angle omnidirectional AR performance. It is believed that such a mathematical treatment applied to these broadband omnidirectional AR (BOAR) structures, as well as the algorithm developed to design such structures are, novel. The simulations performed show why such structures advantageously exhibit not only broadband, but also near omnidirectional, AR characteristics.

To perhaps better understand the interaction of light with these nanostructures on glass, Maxwell's equation is cast as an eigenvalue problem with the well-known operator θ (where the symbols have their usual meaning), such that:

θ=Ε×[(1/∈(r)∇×]

where the frequencies (eigenvalues) of the following equation are admitted through the interface described by the permittivity function ∈ᵣ:

θH(r)=(ω/c)²H(r) (i)

An implication of equation (i) is its scaling property. Assume, for example, that the surface relief structure is scaled by a factor of s, such that r′=s×r, and there is a desire to deduce in a general manner how the scaling relationship in the eigenvalues (ω/c)² evolves.

A simple change in spatial variable r→r′ implies that the constitutive relation in the permittivity function becomes ∈′(r′)=∈(r/s). This transforms equation (i) into:

θH(r)=(ω/sc)²H(r) (ii)

where ∈′(e)=∈(r/s) is the spatial dielectric profile of the structure coating, which corresponds to a spatial profile in which z=f(r, θ), for cylindrical coordinates.

Thus, after scaling the structure by a factor of s, both the eigen frequency of the allowed modes and the permittivity function (related to the refractive index) are scaled accordingly. Such structures therefore provide self similarity at all (or virtually all) scales of light wavelength. As far as the light is concerned, every single photon wavelength (or substantially all single photon wavelengths) can find a matching structure, thereby effectively providing a natural grading of the index.

FIG. 2 is a schematic cross-sectional view of a typical nanostructure with parameters h and d that may be optimized for transmittance. Certain example embodiments are based on an interferometric principle. It is known that η∝∈²−k². Thus, as k approaches 0, η∝\sqrt{∈}. One therefore could in principle draw horizontal lines across the FIG. 2 schematic, finding a refractive index match at each such line based on the structure of nanostructures. As indicated in greater detail below, the nanostructures may be formed from a material of or including titanium oxide (e.g., TiO₂ or other suitable stoichiometry). Thus, it is possible to use a material that typically is considered to be a high index material in connection with a low index of refraction BOAR coating.

FIGS. 3a and 3b help demonstrate how the problem to be solved can be formulated. In that regard, FIG. 3a is a partial perspective view of a formulation of the problem to be solved, and FIG. 3b is a simplified two-dimensional cross-sectional view of the array of dielectric rods shown in FIG. 3a. As will be appreciated from these drawings, the dielectric rods of generally conical structures have a base diameter of b=2R in a generally periodic square lattice with a predefined period a=S.

With the problem conceived as outlined above, the inventor of the instant application has been able to formulate the following equations, which indicate waveguide effects in the transverse magnetic (TMz) and transverse electric (TEz) modes.

For the TMz mode, it has been found that:

$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) , \qquad ( iii )$$

For the TEz mode, it has been found that:

$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3} } {α}^{2} + O ( {α}^{4} ) \qquad ( iv )$$

In equations (iii) and (iv), the symbols take their usual nomenclature. In addition:

a₀=f/∈₂−(1−f)/∈₁, ∈₀=∈₂f−∈₁(1−f), and a=2R/λ₀.

Based on these equations, the FIG. 4 plots reflectance vs. height and wavelength at a fixed cone diameter. The FIG. 4 chart was generated with an example cone base diameter of 200 nm. It can be seen that reflectance is below 2% for the entire chart, regardless of cone height and wavelength. It also can be seen that reflectance is at or below 1% for virtually all wavelengths at cone heights greater than about 600 nm, and at or below 1% for the shown wavelength ranges if the cone height is selected accordingly.

The above set of equations encode the fact that as the height h of these pillars gets larger compared with the base radius, the effective permittivity (proportional to n² for at least some examples) in the Z not only decreases, but there also is a better grading of the isotropic index.

Furthermore, as the density of the nanostructures increases, the matching between the incoming waves and the surface becomes optimized. FIG. 5 illustrates this concept and, more particularly, is a cross-sectional view schematically illustrating a cone-inclusive model that includes a joint probability distribution as to both the diameters and the height of the cones.

Randomization of the structures can in certain example embodiments improve the decoherency factor between the incoming and scattered waves, which in effect may help to attenuate interference effects. This also may help increase the omnidirectionality index in some cases.

It is noted that certain example embodiments may involve the nanostructures being inverted, and thus effectively lie, in the substrate. This approach may in certain example embodiments provide for a more robust or stronger arrangement.

As will be appreciated from the above, the permittivity or index of the material used to form the coating need not always be a limiting factor. That is, the model developed above can take into account materials with different permittivity values (and different refractive indices) and still perform antireflective functions. For example, as alluded to above, high index TiO₂ may be used in certain example embodiments for antireflective purposes in connection with a lower index glass substrate. The ability to use a potentially broader range of materials makes it possible in some instances to imbue the coatings with additional advantageous properties. In the case of TiO₂, for example, the anatase form may be disposed on a substrate in order to imbue the coating with self-cleaning properties. In a similar manner, hydrophobic and hydrophilic coatings may be developed, antibacterial and/or antifungal coatings may be developed (e.g., from zinc oxide and/or zirconium oxide inclusive layers, silver-inclusive layers, etc.), and so on.

Certain example embodiments may be made using a nanolithography masking technique, followed by wet/dry (non-isotropic) etching of the desired structures, e.g., using a focused ion beam. The AR properties of the surface were found to be comparable to high-end existing products, including a conventional four-layer AR coating and Pilkington's Optiview product. FIG. 6 is a graph plotting measured reflectance of substrates including these AR films, as well as the sample AR film produced in accordance with the nanolithography masking technique noted above. In addition to providing low reflectance across the visible spectrum, the sample coating involved a very low reflectance in the near infrared (NIR) spectrum, including very low reflectance from 750-1500 nm or 800-1200 nm as examples. The spectral broadness of the AR property therefore was found to be very advantageous, as was the lower dependence on incident angle (e.g., as compared to the multilayer AR coating).

Because of the low reflectance in the visible and NIR spectra, the AR coatings of certain example embodiments may be particularly well suited to solar photovoltaic cell type applications. Of course, low reflectance in the visible spectrum also could be desirable for commercial or residential windows (including monolithic, laminated, insulating glass, and/or other windows), etc.

An additional advantage of nanostructured AR glass relates to its ability to withstand high incident energies of nearly 50 J/cm². This is a significant improvement over the energy damage threshold of most thin-film anti-reflective coatings. Because the antireflective coating is made of the glass itself or a glass-like material, it may have a dielectric breakdown strength threshold similar to that of the glass itself.

Certain example embodiments also may involve a composite coating, comprising two or more different types of crystalline nanoparticles in a low index matrix. One approach for forming such a coating may involve recognizing and using the different etch rates of the selected materials, e.g., at oblique incidences, to create the desired nanotexture pattern on the surface of the glass.

Sol gel technology also may be used in certain example embodiments and may be advantageous in that it can be used with a potentially broad range of materials, including (for example) silicon-inclusive materials (such as SiOx, SixNy, SiOxNy, etc.). Certain example embodiments may, for example, use a sol that includes alkoxides of one or more different metals. For instance, silica, silica-titania, and/or the like may be used. And as alluded to above, self-cleaning AR coatings may be developed in this way (e.g., when anatase TiO₂ is included in the sol and/or resident in the coating).

One possible scenario for forming a coating in accordance with certain example embodiments involves selectively sensitizing the surface of the glass with an anchor molecule. The anchor molecule may be dispensed as a Langmuir Blodgett on the surface of the glass, for example. The anchor molecule may be activated by shining UV light through a nanoscale mask, nanoprinted onto glass (via additive and/or subtractive techniques), etc. An optimization phase may be used to modify the formed structures (e.g., in terms of morphology, shape, spatial wavelength, height, and/or the like), with a view towards further reducing reflectance, further increasing the spectral broadness of the AR coating, and/or reducing the angular dependence of the AR effect.

FIG. 7 is a flowchart illustrating an example approach for forming an AR coating in connection with certain example embodiments. In step S702, a screen-printing template is designed with the predetermined desirable features. In step S704, a substrate (e.g., glass) is coated with an adhesion promoter in selective areas, e.g., through a screen-printing and/or other approach. In step S706, a precursor (e.g., based on a silicate) may be wet-applied (e.g., via a spin, dip, roll, curtain, slot die, or other coating technique) and self-assembled in a nano-sized domain. Example coating techniques are described in, for example, U.S. Pat. No. 6,383,571, the entire contents of which are hereby incorporated herein by reference. This domain may in certain example embodiments be at least partially defined by the promoter island size through its screenprinting. In step S708, the precursor binds to the functionalized areas of the substrate (e.g., as promoted through UV and/or other optional excitation). The rheology (e.g., viscosity) and/or surface energy of the precursor may be tuned to allow or enable certain structures to evolve. An electric field may optionally be used to help orient or otherwise align supramolecular species in step S710. The substrate with the coating thereon is then annealed and/or the coating is cured (e.g., at a temperature typically less than 500 degrees C., more preferably less than 400 degrees C., and still more preferably less than 300 degrees C.), causing the precursor film to self-assemble into nano-sized domains. An optional lower-temperature drying step may be used prior to the annealing/curing, e.g., to facilitate processability.

This approach may be advantageous in certain example instances, because it potentially enables low-cost manufacturing of silica nanostructures over large areas. In addition, the number of precursor layers can possibly be tuned by the precursor chemistry and/or film thickness. It also may be possible to pattern and/or dope the silica matrix after assembly to provide additional functionality (e.g., self-cleaning properties as indicated above). Existing methods of precursor synthesis generally involve higher temperatures (e.g., 700-1200 degrees C.) and oftentimes use metal substrates (e.g., foils or vacuum-deposited films) and siloxane or Si and carbon containing gas or liquid precursors. These alternative conditions may be problematic in terms of manufacturing such structures on soda lime glass, and process compatibility with glass typically is desirable for applications including transparent conductors, e.g., for windows, displays, etc. The self-assembly of siloxane from supramolecular precursors may, however, alleviate at least some of these concerns, e.g., because of the possibility of using lower-temperature precursors.

Any suitable chemistry for the sols may be used. For example, the sols may be based on TEOS, ormosil, TEOS optimized with ormosil, polysilazane, butylacetate diluted polysilazane, polysilazane mixed with ormosil (e.g., in a near 1:1 ratio), etc.

It is noted that porogens may or may not be included in the sol. Samples were made, increasing transmission by 3% per side with no or substantially no interference fringes in a wavelength range 240-1200 nm. For example, a first layer with a first porogen concentration and/or distribution is provided. The porogens preferably are miscible with a silica-based sol gel and can be easily removed (e.g., through a heating or etching process). A porous sol-gel film is formed following removal. Layers may be successively formed in this manner with increasing porosity, potentially in the desired pattern. In other words, porogen concentration and film thickness can be optimized on a layer-by-layer basis for increasing transmission, e.g., by forming nanostructures that at least generally conform to the models above.

Another example approach that may be used in connection with certain example embodiments involves embossed or mold structures. Sols may be wet coated on a substrate (e.g., via dip, spin, roll, curtain, slot die, or other technique). The substrate with the sol thereon may be heated to at least partially cure the material. A relatively low temperature that preferably is less than 400 degrees C., more preferably less than 300 degrees C., still more preferably less than 250 degrees C., and sometimes less than 200 degrees C. may be used. For instance, heat may be applied at 140 degrees C. for 10-15 minutes. A stamp with the desired pattern may be applied to the partially cured sol. A vacuum may be used to increase the pressure. After a time and potentially after a more complete curing process (e.g., at a temperature that is higher than the temperature associated with the initial drying but preferably less than 500 degrees C.), the stamp may be removed. A release agent may be applied between the sol and the stamp prior to the stamp being applied in certain example embodiments in order to facilitate its “clean” removal. The release layer may be dissolved using any appropriate material. TEOS, TMOS, polysilazane, and/or other solutions may be used for the sol in different example embodiments, and it will be appreciated that the gel time may vary based on the material(s) selected. For instance, the gel times may range from several minutes to an hour or more. In some cases it may take up to a day or more for the stamp (with pressure applied) to form a high quality pattern.

The following data was obtained from a sample made with a PDMS and pluronic acid:

| | Sol Gel AR | | | | Solar T | |
|---|---|---|---|---|---|---|
| | Peak | % TQE | | | ISO 9050 | GreenHouse |
| | Wave- | (400-1200 nm avg) | | | AM1.5 | NEN2675 |
| Sample | length | Uncoated | Coated | Gain | Coated | Coated |
| 1 | 505 | 92.23 | 94.15 | 1.92 | 94.46 | 94.79 |
| 2 | 495 | 92.59 | 94.45 | 1.86 | 94.45 | 95.08 |
| 3 | 515 | 94.87 | 95.85 | 0.98 | 95.86 | 96.37 |
| 4 | 555 | 98.01 | 98.58 | 0.57 | 98.57 | 98.74 |
| 5 | 1655 | 98.76 | 98.24 | −0.52 | 98.19 | 98.10 |

| | Visible Color | | | | | | | |
|---|---|---|---|---|---|---|---|---|
| | (Ill. D65 obs./10 deg.) | | | | (Ill. D65 obs./10 deg.) | | | |
| Sample | Tvis | L* | a* | b* | Tvis | L* | a* | b* |
| 1 | 95.18 | 98.11 | −0.14 | 0.08 | 95.18 | 98.11 | −0.14 | 0.07 |
| 2 | 95.18 | 98.10 | −0.13 | 0.05 | 95.17 | 98.10 | −0.14 | 0.04 |
| 3 | 96.44 | 98.61 | −0.10 | 0.00 | 96.43 | 98.60 | −0.10 | 0.00 |
| 4 | 98.77 | 99.52 | −0.04 | 0.03 | 98.77 | 99.52 | −0.04 | 0.03 |
| 5 | 98.11 | 99.27 | 0.00 | 0.11 | 98.12 | 99.27 | −0.01 | 0.12 |

The following data was obtained from a sample made with a siloxane base:

| | Sol Gel AR | | | | Solar T | Green- |
|---|---|---|---|---|---|---|
| | Peak | % TQE | | | ISO 9050 | House |
| | Wave- | (400-1200 nm avg) | | | AM1.5 | NEN2675 |
| Sample | length | Uncoated | Coated | Gain | Coated | Coated |
| 1 | 555 | 92.23 | 94.08 | 1.86 | 94.34 | 94.53 |
| 2 | 580 | 92.59 | 93.67 | 1.08 | 93.59 | 94.10 |
| 3 | 560 | 94.87 | 90.92 | −3.96 | 90.84 | 91.54 |
| 4 | 500 | 98.01 | 84.48 | −13.53 | 84.47 | 85.44 |
| 5 | 500 | 98.76 | 71.52 | −27.24 | 71.61 | 72.88 |

| | Visible Color | | | | | | | |
|---|---|---|---|---|---|---|---|---|
| | (Ill. D65 obs./10 deg.) | | | | (Ill. D65 obs./10 deg.) | | | |
| Sample | Tvis | L* | a* | b* | Tvis | L* | a* | b* |
| 1 | 94.95 | 98.01 | −0.11 | 0.25 | 94.96 | 98.02 | −0.14 | 0.25 |
| 2 | 94.23 | 97.73 | −0.11 | 0.31 | 94.25 | 97.73 | −0.15 | 0.31 |
| 3 | 91.69 | 96.69 | −0.16 | 0.30 | 91.70 | 96.70 | −0.19 | 0.29 |
| 4 | 85.58 | 94.13 | −0.22 | 0.07 | 85.58 | 94.13 | −0.22 | 0.05 |
| 5 | 72.99 | 88.44 | −0.30 | −0.29 | 72.95 | 88.43 | −0.25 | −0.32 |

Yet another example approach that may be used in connection with certain example embodiments involves asymmetric phase separation, and this approach is outlined in the FIG. 8 example flowchart. A suitable material may be deposited via one or more of the wet application techniques identified above in step S802. A quick drying process may be used after the wet application of the material in step S804. The material preferably self-organizes into nanostructures with the desired characteristics. Benard cells preferably are used and surface tensions, relative viscosity, capillary actions, and relative densities of the materials aid in the self-assembly. Thus, the materials (which may include, for example, pluronic acid, silica-based sol gels including TEOS and/or TMOS, polysilazane solutions, etc.) may have these properties properly balanced to self-assemble in the desired manner. Thus, the film is allowed to self-assemble in step S806. The secondary phase may be removed, e.g., once the phases have separated, in step S808. The remaining phase, which preferably has the desired nanostructures, may be finally cured, e.g., at the elevated temperatures noted above, in step S810.

In one example, 10 mL titanium isopropoxide was added to 0.5 mL nitric acid, 1 mL of deionized water, and 300 mL of isopropanol. This solution was dispensed with a slot die coater, and the Benard cells appeared as the films were dispensed and dried. The features and period were found to depend on the dispensing rate vs. evaporation rate. This parameter may be tuned in addition to those specified above to provide good results. For instance, a voltage can be applied to the slot of a slot die coater to influence, for example, the balance between the viscosity, gravity, thermocapillary action, and inertial forces, e.g., to provide a high-quality coating. It is noted that any metal (including Si) alkoxide may be used in this or a similar format. For example, the inventor has successfully mixed alkoxides for example, with Ti, Si, and Ce, to provide hollow cells with a sufficient regularity and very good periodicity.

Using this sample, the following data was obtained:

| | | | | | % TQE_400 to | | | ISO 9050 | |
|---|---|---|---|---|---|---|---|---|---|
| | Y/Tvis | | | | 1200 avg | | | AM1.5 | |
| Sample | (D6510) | L* | a* | b* | Uncoated | Coated | Gain | Coated | Change (avg.) |
| REF 1 | 91.14 | 96.47 | −0.16 | 0.19 | 89.98 | 89.97 | 89.95 | 90.06 | 90.04 |
| REF 2 | 91.10 | 96.45 | −0.16 | 0.20 | 89.98 | 89.93 | | 90.03 | |
| NO 1 | 94.55 | 97.85 | −0.05 | 0.67 | 89.98 | 94.28 | 4.30 | 94.10 | 4.06 |
| NO 2 | 93.16 | 97.29 | 0.35 | −0.08 | 89.98 | 93.50 | 3.51 | 93.28 | 3.24 |
| NO 3 | 92.97 | 97.22 | 0.96 | −0.32 | 89.98 | 93.22 | 3.23 | 93.41 | 3.36 |
| NO 4 | 92.36 | 96.97 | 0.33 | −0.11 | 89.98 | 93.62 | 3.64 | 93.39 | 3.35 |
| NO 5 | 94.96 | 98.02 | −0.06 | 0.83 | 89.98 | 94.64 | 4.66 | 94.42 | 4.37 |

Using the example techniques described herein, it sometimes is possible to achieve visible transmission gains of 3-4%, per side of the substrate on which the example AR coating is provided. In certain example embodiments, transmission gains of at least 2-3% are achieved over a wavelength range of 400-1200 nm.

As indicated above, certain example embodiments may be used in connection with photovoltaic devices. Photovoltaic devices are disclosed in, for example, U.S. Pat. Nos. 8,022,291; 7,875,945; 6,784,361; 6,288,325; 6,613,603; and 6,123,824; U.S. Publication Nos. 2011/0180130; 2011/0100445; 2009/0194157; 2009/0032098; 2008/0169021; and 2008/0308147; and application Ser. No. 13/455,317 filed Apr. 25, 2012; Ser. No. 13/455,300 filed Apr. 25, 2012; Ser. No. 13/455,282 filed Apr. 25, 2012; and Ser. No. 13/455,232 filed Apr. 25, 2012, the disclosures of which are hereby incorporated herein by reference. The AR coatings disclosed herein may be used in connection with any photovoltaic device, whether it be an a-Si, CIS/CIGS, c-Si, or other photovoltaic device.

FIG. 9 is an example photovoltaic device incorporating an AR coating made in accordance with certain example embodiments. In the FIG. 9 example embodiment, a glass substrate 902 is provided. The glass may be soda lime silica based glass, low-iron glass (e.g., in accordance with one of the references listed below), etc. A BOAR coating 904 of the type disclosed herein may be provided on an exterior surface of the glass substrate 902, e.g., to increase transmission. One or more absorbing layers 906 may be provided on the glass substrate 902 opposite the AR coating 904, e.g., in the case of a back electrode device such as that shown in the FIG. 9 example embodiment. The absorbing layer(s) 906 may be sandwiched between first and second semiconductors. In the FIG. 9 example embodiment, absorbing layer(s) 906 are sandwiched between n-type semiconductor layer 908 (closer to the glass substrate 902) and p-type semiconductor layer 910 (farther from the glass substrate 902). A back contact 912 (e.g., of or including aluminum or other suitable material) also may be provided. First and second transparent conductive coatings (TCCs) 914 and 916, which may be transparent conductive oxides (TCOs) such as, for example, ITO or the like, may be provided between the semiconductor 908 and the glass substrate 902 and/or between the semiconductor 910 and the back contact 912. It will of course be appreciated that there are other types of solar photovoltaic devices, and the AR coating disclosed herein may be used in connection with these other types of solar photovoltaic devices.

Although certain example embodiments have been described in connection with nanostructures comprising cones, it will be appreciated that cone-like and/or other structures may be used in different example embodiments. For example, shapes that are substantially cylindrical, rectangular prisms, etc., may be used, and the models may be updated accordingly.

Although certain example embodiments have been described in connection with photovoltaic devices, windows, displays, and/or the like, the example embodiments described herein may be used in connection with any end application where AR coatings are desirable.

Certain example embodiments may be used in connection with soda lime silicate glass, and/or so-called low-iron glass. For instance, the substrate in FIG. 8, for example, may be a low-iron glass substrate. Low-iron glass is described in, for example, U.S. Pat. Nos. 7,893,350; 7,700,870; 7,557,053; 6,299,703; and 5,030,594, and U.S. Publication Nos. 2006/0169316; 2006/0249199; 2007/0215205; 2009/0223252; 2010/0122728; 2010/0255980; and 2011/0275506. The entire contents of each of these documents are hereby incorporated herein by reference.

The substrates described herein may be heat treated (e.g., heat strengthened and/or thermally tempered), and/or chemically tempered, in certain example embodiments. The terms “heat treatment” and “heat treating” as used herein mean heating the article to a temperature sufficient to achieve thermal tempering and/or heat strengthening of the glass inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, or up to about 10 minutes, in certain example embodiments.

It is noted that certain example embodiments may not achieve the exact structure indicated by these equations. Thus, although certain example embodiments are described as providing nanostructures that meet these criteria, approximate these equations, and/or are formed “in accordance” with the equations, it will be appreciated that an exact match is not required. Instead, there may be some tolerance for at least manufacturing variations, incidental or deviations, etc. In some situations, nanostructures may meet these criteria, approximate these equations, and/or be formed “in accordance” with the equations, provided that they serve the same or similar functions/provide a performance boost (e.g., in terms of visible transmission gain and/or reflection reduction) as set forth herein.

In certain example embodiments, there is provided a method of making a coated article comprising an AR coating supported by a glass substrate. A solution is dispensed onto at least one major surface of the glass substrate. The solution is dried at a first temperature. Benard cells are formed and/or allowed to form during the dispensing and/or drying, with the Benard cells causing nanostructures to self-assemble on the at least one major surface of the glass substrate in accordance with a desired template. The desired template exhibiting waveguide modes that approximate: (a) a transverse magnetic (TMz) mode in which

$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$

and/or (b) a transverse electric (TEz) mode in which

$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3} } {α}^{2} + O ( {α}^{4} ) ,$$

where a₀=f/∈₂−(1−f)/∈₁, ∈₀=∈₂f−∈₁(1−f), and a=2R/λ₀. At least a part of the solution is cured at a second temperature that is higher than the first temperature in forming the AR coating.

In addition to the features of the previous paragraph, in certain example embodiments, the solution may asymmetrically phase separate into first and second phases.

In addition to the features of the previous paragraph, in certain example embodiments, the first phase may be removed prior to the curing, with the curing optionally being performed with respect to the second phase. For instance, the curing may be performed once the first and second phases have substantially separated from one another (e.g., once phase separation is 51% complete, 75% complete, or 90-95% or more complete).

In addition to the features of any of the three previous paragraphs, in certain example embodiments, the curing may be performed once a substantial portion of the nanostructures have self-assembled (e.g., once self-assembly is 51% complete, 75% complete, or 90-95% or more complete).

In addition to the features of any of the four previous paragraphs, in certain example embodiments, the first temperature may be less than 200 degrees C. and/or the second temperature may be less than 500 degrees C.

In addition to the features of any of the five previous paragraphs, in certain example embodiments, the solution may include titanium isopropoxide, nitric acid, deionized water, and isopropanol. Alternatively, or in addition, in certain example embodiments, the solution may include a metal and/or Si inclusive alkoxide. For instance, in certain example embodiments, the solution may include alkoxides mixed with a high index of refraction material (e.g., Ti, Si, and/or Ce). In certain example embodiments, the nanostructures may be formed primarily from the high index of refraction material.

In addition to the features of any of the six previous paragraphs, in certain example embodiments, the AR coating may provide an average transmission gain of 2-3% (more preferably 3-4%) achieved over a wavelength range of 400-1200 nm.

In addition to the features of any of the seven previous paragraphs, in certain example embodiments, the average transmission gain is present for substantially all incidence angles (e.g., preferably at angles at least 30 degrees from normal, more preferably at least 45 degrees from normal, still more preferably at least 60-75 degrees from normal, and sometimes at least 80-85 degrees from normal).

In addition to the features of any of the eight previous paragraphs, in certain example embodiments, the dispensing of the solution may be practiced in cooperation with a slot die coater.

In addition to the features of the previous paragraph, in certain example embodiments, the solution may asymmetrically separate into first and second phases, the first phase may be removed prior to the curing, and/or the curing may be performed with respect to the second phase, e.g., once the first and second phase substantially separate from one another.

In addition to the features of either of the two previous paragraphs, in certain example embodiments, surface tensions, relative viscosities, and/or relative densities of materials used to form the first and second phases may be balanced to promote self-assembly of the nanostructures.

In addition to the features of any of the three previous paragraphs, in certain example embodiments, a voltage may be applied to a slot of the slot die coater to balance viscosity, gravity, thermocapillary action, and/or inertial forces, in dispensing the solution on the glass substrate.

In addition to the features of any of the 12 previous paragraphs, in certain example embodiments, the nanostructures may be generally conical in shape.

In addition to the features of any of the 13 previous paragraphs, in certain example embodiments, the nanostructures may comprise a material that, if coated separately, would have an index of refraction of at least 1.8. The nanostructures may in certain example embodiments comprise Ti, Si, and/or Ce. Anatase TiO₂, for instance, may be used in certain example embodiments.

In addition to the features of any of the 13 previous paragraphs, in certain example embodiments, the AR coating may be provided on first and second major surfaces of the substrate.

These example methods may be used to make electronic devices (e.g., photovoltaic devices, touch screen devices, display devices, etc.), windows (e.g., insulating glass units, vacuum insulating glass units, etc., for commercial and/or residential uses). In general, in certain example embodiments, a coated article made in accordance with any of the 14 previous paragraphs may be provided, and the coated article may be built into an intermediate and/or end product. One example involves a method of making a photovoltaic device, which may comprise (for example): providing a coated article made according to the method of any of the 14 previous paragraphs; and on a surface opposite the AR coating, forming at least the following layers, in order, moving away from the substrate, a first transparent conductive coating, a first semiconductor layer, one or more absorbing layers, a second semiconductor layer, and a second transparent conductive coating. In a similar vein, certain example embodiments relate to a coated article and/or intermediate or end product produced in accordance with any of the techniques and/or having any of the features set forth in any of the preceding 14 paragraphs.

In this regard, certain example embodiments relate to a coated article, comprising: a glass substrate; and an antireflective (AR) coating formed on at least one major surface of the substrate. The AR coating is patterned so as to exhibit waveguide modes that approximate (a) a TMz mode in which

$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$

and (b) a TEz mode in which

$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3} } {α}^{2} + O ( {α}^{4} ) ,$$

where a₀=f/∈₂−(1−f)/∈₁, ∈₀=∈₂f−∈₁−∈₁(1−f), and a=2R/λ₀. The AR coating may, for example, provide an average transmission gain of at least 2% achieved over a wavelength range of 400-1200 nm at substantially all angles of incidence.

Although an element, layer, layer system, coating, or the like, may be said to be “on” or “supported by” a substrate, layer, layer system, coating, or the like, other layers and/or materials may be provided therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a coated article comprising an antireflective (AR) coating supported by a glass substrate, the method comprising:
dispensing a solution onto at least one major surface of the glass substrate;
drying the solution at a first temperature;
forming Benard cells and/or allowing Benard cells to form during the dispensing and/or drying, the Benard cells causing nanostructures to self-assemble on the at least one major surface of the glass substrate in accordance with a desired template, the desired template exhibiting waveguide modes that approximate:
(a) a transverse magnetic (TMz) mode in which
$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$
and/or
(b) a transverse electric (TEz) mode in which
$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3} } {α}^{2} + O ( {α}^{4} ) ,$$
where a₀=f/∈₂−(1−f)/∈₁, ∈₀=∈₂f−∈₁(1−f), and a=2R/λ₀; and
curing at least a part of the solution at a second temperature that is higher than the first temperature in forming the AR coating.

2. The method of claim 1, wherein the solution asymmetrically phase separates into first and second phases.

3. The method of claim 2, wherein the first phase is removed prior to the curing, the curing being performed with respect to the second phase.

4. The method of claim 2, wherein the curing is performed once a substantial portion of the nanostructures have self-assembled.

5. The method of claim 2, wherein the curing is performed once the first and second phases have substantially separated from one another.

6. The method of claim 1, wherein the first temperature is less than 200 degrees C.

7. The method of claim 6, wherein the second temperature is less than 500 degrees C.

8. The method of claim 1, wherein the second temperature is less than 500 degrees C.

9. The method of claim 1, wherein the solution includes titanium isopropoxide, nitric acid, deionized water, and isopropanol.

10. The method of claim 1, wherein the solution includes a metal and/or Si inclusive alkoxide.

11. The method of claim 1, wherein the solution includes alkoxides mixed with a high index of refraction material.

12. The method of claim 11, wherein the high index of refraction material comprises Ti, Si, and/or Ce.

13. The method of claim 1, wherein the nanostructures are primarily formed from the high index of refraction material.

14. The method of claim 1, wherein the AR coating provides an average transmission gain of 2-3% achieved over a wavelength range of 400-1200 nm.

15. The method of claim 1, wherein the AR coating provides an average transmission gain of 3-4% achieved over a wavelength range of 400-1200 nm.

16. The method of claim 15, wherein the average transmission gain is present for substantially all incidence angles.

17. The method of claim 1, wherein the dispensing of the solution is practiced in cooperation with a slot die coater.

18. The method of claim 1, wherein the solution asymmetrically separates into first and second phases, the first phase being removed prior to the curing, the curing being performed with respect to the second phase once the first and second phase substantially separate from one another.

19. The method of claim 18, wherein surface tensions, relative viscosities, and relative densities of materials used to form the first and second phases are balanced to promote self-assembly of the nanostructures.

20. The method of claim 17, further comprising applying a voltage to a slot of the slot die coater to balance viscosity, gravity, thermocapillary action, and/or inertial forces, in dispensing the solution on the glass substrate.

21. A coated article, comprising:
a glass substrate; and
an antireflective (AR) coating formed on at least one major surface of the substrate,
wherein the AR coating is patterned so as to exhibit waveguide modes that approximate:
(a) a transverse magnetic (TMz) mode in which
$${ɛ}_{eff} = {ɛ}_{0} + {\frac{{π}^{2}}{3} [ f ( 1 - f ) ( {ɛ}_{2} - {ɛ}_{1} ) ]}^{2} {α}^{2} + O ( {α}^{4} ) ,$$
and
(b) a transverse electric (TEz) mode in which
$${ɛ}_{eff} = \frac{1}{{a}_{0}} + {\frac{{π}^{2}}{3} [ f ( 1 - f ) \frac{( {ɛ}_{2} - {ɛ}_{1} )}{{ɛ}_{2} {ɛ}_{1}} ]}^{2} \frac{{ɛ}_{0}}{{a}_{0}^{3} } {α}^{2} + O ( {α}^{4} ) ,$$
where
a₀=f/∈₂−(1−f)/∈₁, ∈₀=∈₂f−∈₁(1−f), and a=2R/λ₀,
wherein the AR coating provides an average transmission gain of at least 2% achieved over a wavelength range of 400-1200 nm at substantially all angles of incidence.

22. The coated article of claim 21, wherein the nanostructures are generally conical in shape.

23. The coated article of claim 21, wherein the nanostructures comprise a material that, if coated separately, would have an index of refraction of at least 1.8.

24. The coated article of claim 21, wherein the nanostructures comprise Ti, Si, and/or Ce.

25. The coated article of claim 21, wherein the nanostructures comprise anatase TiO₂.

26. The coated article of claim 21, wherein the AR coating provides an average transmission gain of at least 3% achieved over a wavelength range of 400-1200 nm at substantially all angles of incidence.

27. The coated article of claim 21, wherein the AR coating is provided on first and second major surfaces of the substrate.

28. A method of making a photovoltaic device, the method comprising:
providing a coated article made according to the method of claim 1; and
on a surface opposite the AR coating, forming at least the following layers, in order, moving away from the substrate:
a first transparent conductive coating;
a first semiconductor layer;
one or more absorbing layers;
a second semiconductor layer; and
a second transparent conductive coating.

29. An electronic device comprising the coated article of claim 21.

30. A window comprising the coated article of claim 21.
